(19) United States
(12) Patent Application Publication
(10) Pub. No.: US 2023/0189479 A1
(43) Pub. Date: Jun. 15, 2023

(54) STAGGERED MULTI-LAYER HEAT EXCHANGER

(71) Applicant: Dell Products L.P., Round Rock, TX (US)

(72) Inventor: Yu-Ming Kuo, New Taipei City (TW)

(21) Appl. No.: 17/644,379

(22) Filed: Dec. 15, 2021

(51) Int. Cl. H05K 7/20; F28F 13/12

(52) U.S. Cl. CPC H05K 7/2039; F28F 13/12; H05K 7/20736; F28F 2250/08; F28F 2250/102

(57) ABSTRACT

A cooling system for an information handling system comprises a fan with a sunflower type heat exchanger having two heat exchanger bodies separated by a gap and rotationally offset an angle sized such that a fin of the first heat exchanger body is aligned relative to a channel between two adjacent fins of the second heat exchanger body. As airflow flows through channels between adjacent fins of the first heat exchanger body, the air temperature increases. Air exiting the first heat exchanger body mixes with a second airflow entering the gap between the two heat exchanger bodies and the combined airflow is cooler and turbulent for additional heat absorbing capability for improved cooling.

### BACKGROUND

### Field of the Disclosure

This disclosure relates generally to systems for cooling components information handling systems and, more particularly, to cooling systems with staggered multi-layer heat exchangers.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

Embodiments disclosed herein may be generally directed to information handling systems and cooling systems for cooling components in an information system in a chassis.

Embodiments of a sunflower type heat exchanger may comprise a central core, a first heat exchanger body comprising a first plurality of fins extending radially outward from the central core and a second heat exchanger body comprising a second plurality of fins extending radially outward from the central core. The first heat exchanger body is separated from the second heat exchanger body by a gap and the first heat exchanger body is rotationally offset relative to the second heat exchanger body.

Embodiments of a cooling system for an information handling system may comprise a fan operable to draw air in an axial direction and a heat exchanger positioned coaxial with the fan, the heat exchanger comprising a central core, a first heat exchanger body comprising a first plurality of fins extending radially outward from the central core; and a second heat exchanger body comprising a second plurality of fins extending radially outward from the central core.

Embodiments of a method of manufacturing a cooling system for an information handling system comprise assembling a heat exchanger including positioning a first heat exchanger body on a central core, wherein the first heat exchanger body comprises a first plurality of fins extending radially outward from the central core, positioning a second heat exchanger body on the central core with a radially offset and a gap relative to the first heat exchanger body, wherein the second heat exchanger body comprises a second plurality of fins extending radially outward from the central core, and positioning the heat exchanger coaxially with a fan.

In some embodiments, the rotational offset between the first heat exchanger body and the second heat exchanger body causes turbulence in airflow entering the second heat exchanger body. In some embodiments, the rotational offset between the first heat exchanger body and the second heat exchanger body aligns each fin of the first plurality of fins relative to a channel between two adjacent fins of the second plurality of fins. In some embodiments, the first heat exchanger body is rotationally offset less than five degrees relative to the second heat exchanger body. In some embodiments, the gap between the first heat exchanger body and the second heat exchanger body causes turbulence in airflow entering the second heat exchanger body.

### BRIEF DESCRIPTION OF THE DRAWINGS

For a more complete understanding of the invention and its features and advantages, reference is now made to the following description, taken in conjunction with the accompanying drawings, in which:

FIG. 1 depicts a block diagram of an information handling system in a chassis;

FIG. 2 depicts a side view of one embodiment of a cooling system for an information handling system in a chassis, illustrating a sunflower type heat exchanger with fins extending radially outward and a fan drawing airflow in an axial direction;

FIG. 3 depicts a side view of one embodiment of a sunflower type heat exchanger, illustrating how a fully developed fluid field may reduce heat transfer capacity or efficiency of the sunflower type heat exchanger;

FIGS. 4A and 4B depict simulated temperature profiles of the sunflower type heat exchanger depicted in FIG. 2, illustrating a large increase in the surface temperature of fins from a first end to a second end;

FIG. 5 depicts a side view of one embodiment of a cooling system with a multi-layer sunflower type heat exchanger with rotationally offset heat exchanger bodies for cooling an information handling system in a chassis, illustrating air flows through multiple heat exchanger bodies; and

FIGS. 6A and 6B depict simulated temperature profiles of one embodiment of a heat exchanger for use in a cooling system for an information handling system.

### DESCRIPTION OF PARTICULAR EMBODIMENT(S)

In the following description, details are set forth by way of example to facilitate discussion of the disclosed subject matter. It should be apparent to a person of ordinary skill in the field, however, that the disclosed embodiments are exemplary and not exhaustive of all possible embodiments.

As used herein, a hyphenated form of a reference numeral refers to a specific instance of an element and the un-hyphenated form of the reference numeral refers to the collective or generic element. Thus, for example, heat exchanger “206-1” refers to an instance of a heat exchanger, which may be referred to collectively as heat exchangers “206” and any one of which may be referred to generically as heat exchanger “206.”

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and one or more video displays. The information handling system may also include one or more buses operable to transmit communication between the various hardware components.

Embodiments disclosed herein are described with respect to an information handling system contained in a chassis. Embodiments disclosed herein include a multi-layered heat exchanger for cooling information handling systems.

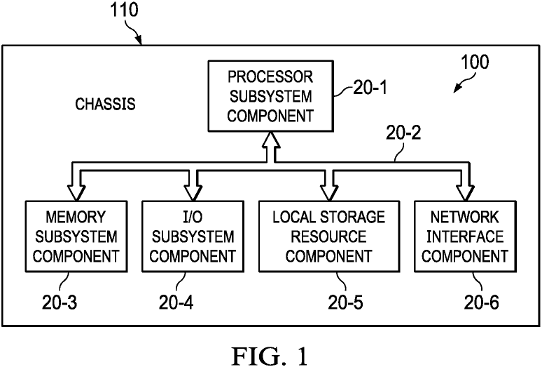

Particular embodiments are best understood by reference to FIGS. 1-2, 3A-3B, 4, 5 and 6A-6B, wherein like numbers are used to indicate like and corresponding parts.

Turning to the drawings, FIG. 1 depicts a block diagram of an information handling system 100.

Information handling system 100 may contain components 20-1 of a processor subsystem comprising a system, device, or apparatus operable to interpret and execute program instructions and process data, and may include a microprocessor, microcontroller, digital signal processor (DSP), application specific integrated circuit (ASIC), or another digital or analog circuitry configured to interpret and execute program instructions and process data. In some embodiments, components 20-1 of a processor subsystem may interpret and execute program instructions and process data stored locally (e.g., in a memory subsystem). In the same or alternative embodiments, components of a processor subsystem may interpret and execute program instructions and process data stored remotely (e.g., in a network storage resource).

Information handling system 100 may contain components 20-3 of a memory subsystem comprising a system, device, or apparatus operable to retain and retrieve program instructions and data for a period of time (e.g., computer-readable media). Components 20-3 of a memory subsystem may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

Information handling system 100 may contain components 20-4 of an input/output (I/O) subsystem comprising a system, device, or apparatus generally operable to receive and transmit data to or from or within information handling system 100. Components 20-4 of an I/O subsystem may represent, for example, a variety of communication interfaces, graphics interfaces, video interfaces, user input interfaces, and peripheral interfaces. In various embodiments, components 20-4 of an I/O subsystem may be used to support various peripheral devices, such as a touch panel, a display adapter, a keyboard, a touch pad, or a camera, among other examples. In some implementations, components 20-4 of an I/O subsystem may support so-called ‘plug and play’ connectivity to external devices, in which the external devices may be added or removed while information handling system 100 is operating.

Information handling system 100 may contain components 20-5 of a local storage resource comprising computer-readable media (e.g., hard disk drive, floppy disk drive, CD-ROM, and other type of rotating storage media, flash memory, EEPROM, or another type of solid-state storage media) and may be generally operable to store instructions and data.

Information handling system 100 may contain components 20-6 of a network interface comprising a suitable system, apparatus, or device operable to serve as an interface between information handling system 100 and a network (not shown). Components 20-6 of a network interface may enable information handling system 100 to communicate over a network using a suitable transmission protocol or standard. In some embodiments, components 20-6 of a network interface may be communicatively coupled via a network to a network storage resource (not shown). A network coupled to components 20-6 of a network interface may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, the Internet or another appropriate architecture or system that facilitates the communication of signals, data and messages (generally referred to as data). A network coupled to components 20-6 of a network interface may transmit data using a desired storage or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), or any combination thereof. A network coupled to components 20-6 of a network interface or various components associated therewith may be implemented using hardware, software, or any combination thereof.

Information handling system 100 may contain components 20-2 of a system bus comprising any of a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

In information handling system 100, components 20 may generate heat that must be transferred to the ambient environment.

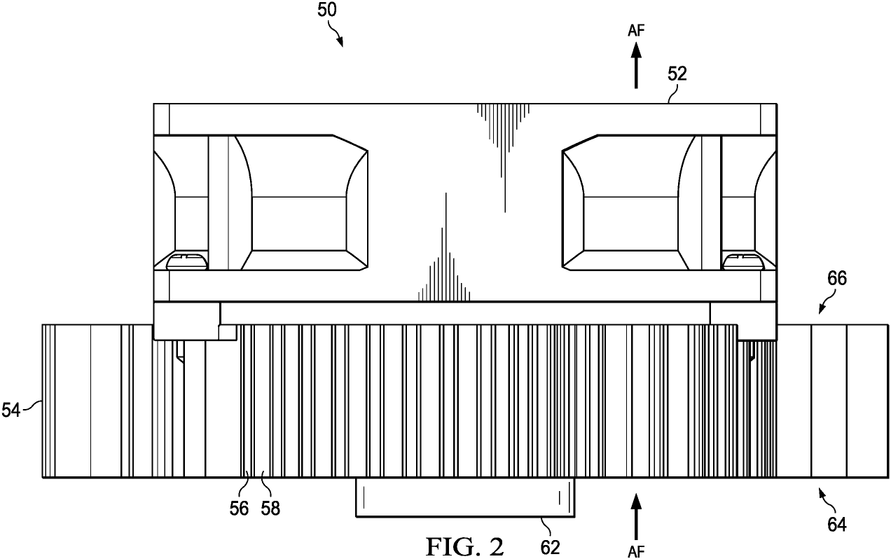

FIG. 2 depicts a side view of a cooling system with a cooling system 200 comprising an axial fan 52 with a heat exchanger 54 commonly referred to as a sunflower-type heat exchanger. As depicted in FIG. 2, heat exchanger 54 comprises a central core 56 with a plurality of fins 58 extending radially outward, with each fin separated from an adjacent fin 58 by a channel 60. Fins 58 may be formed of a material to conduct heat radially outward for exposure to airflow (AF) flowing from first end 64 to second end 66. In operation, heat is transferred to heat exchanger 54 through central core 62 and fan 52 draws airflow (AF) in an axial direction to flow through channels 60 in heat exchanger 54 and through fan 52 for convective heat transfer out of cooling system 200.

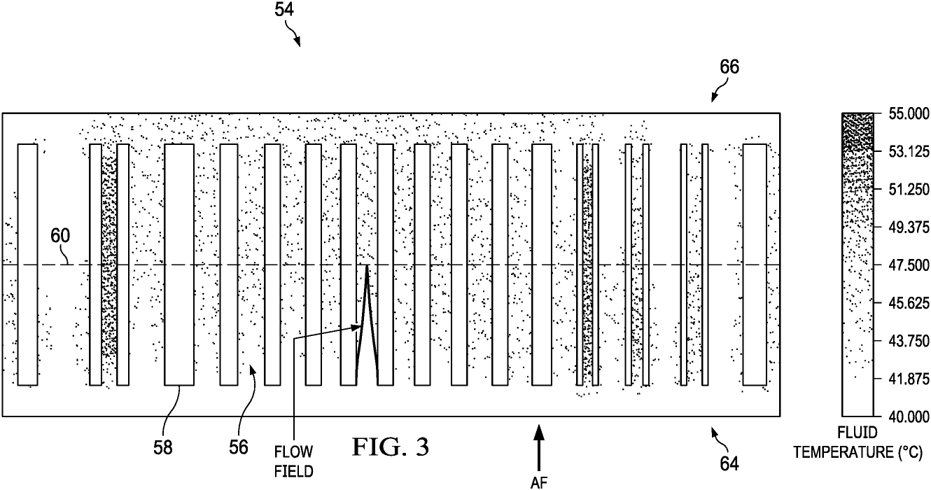

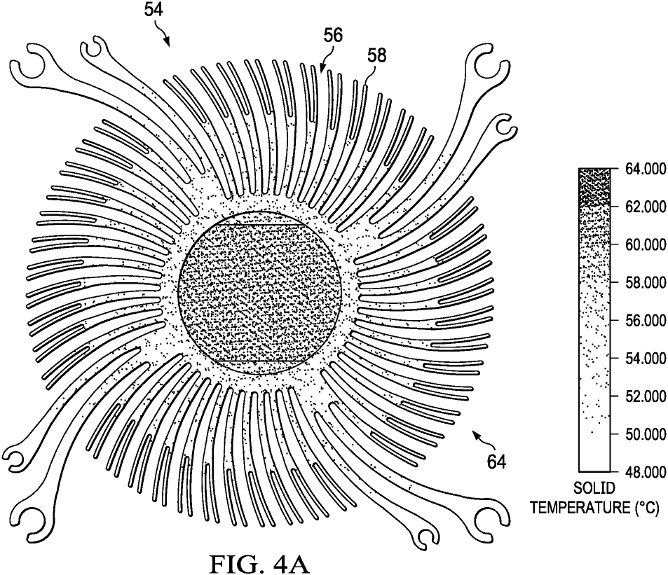

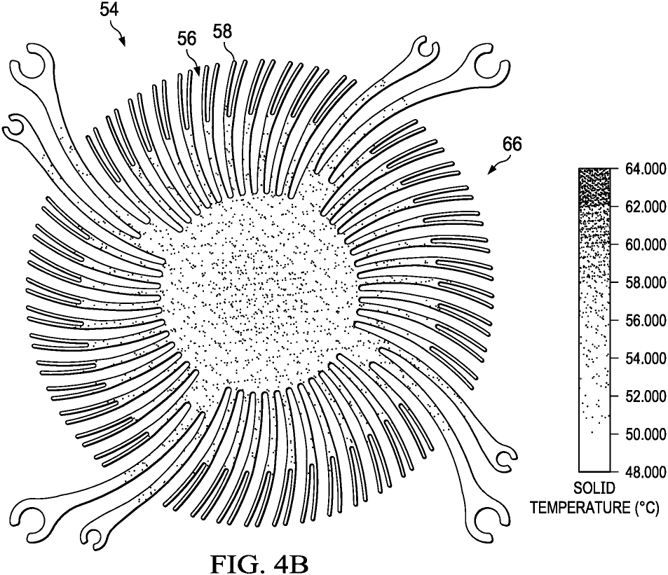

An issue with this design is that heat conduction in fins 58 also occurs in an axial direction. Referring to FIGS. 3A-3B and 4, in a traditional cooling system with a one-piece heat exchanger 54, airflow AF flows through the whole length of each channel 56. As depicted in FIG. 3A, airflow AF at a first temperature (e.g., 20 C) enters first end 64 and heat transfer from fins 58 to airflow AF may be efficient. As depicted in FIG. 3B, airflow AF exiting second end 66 may be at a much higher temperature such that heat transfer from fins 58 is inefficient or does not occur, which limits the cooling performance of cooling system 200. A reason for this may be that, referring to FIG. 4, at some point (e.g., around midpoint 60) the fluid field becomes fully developed flow, which limits the ability for fins 58 to transfer heat to airflow AF.

Increased power usage by newer information handling systems 100 will only result in more heat generation. Using cooling system 200 with heat exchanger 54 and axial fan 52, information handling system 100 may be unable to operate at higher processing levels due to an inability of heat exchanger 54 to effectively transfer heat to airflow AF.

Embodiments disclosed herein increase cooling capabilities within chassis 110 with a multi-layered sunflower-type heat exchanger having two heat exchanger bodies that may be separated by a gap to allow cool airflow to enter the heat exchanger and the two heat exchanger bodies may be rotationally offset such that airflow exiting the first heat exchanger body mixes with cool airflow and the combined airflow is turbulent as it enters the second heat exchanger body.

### Heat Exchanger Is Split Into Two Heat Exchanger Bodies

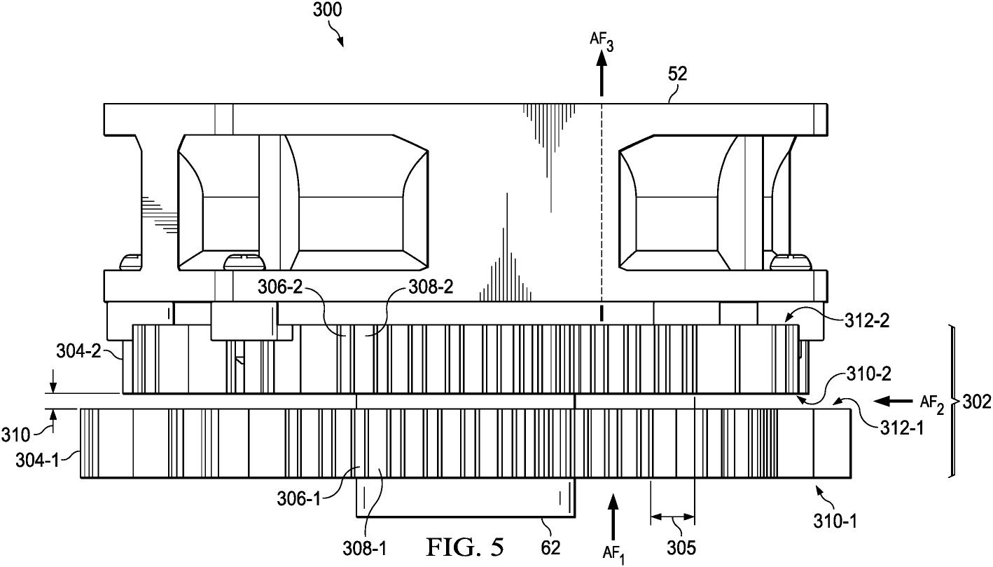

FIG. 5 depicts a side view of one embodiment of a cooling system for cooling selected components of information handling system 100.

As depicted in FIG. 5, embodiments of cooling system 300 assembled with axial fan 52 coupled to heat exchanger 302 comprising two heat exchanger bodies 304-1 and 304-2 that are separated by a gap 310 and rotationally offset.

Each heat exchanger body 304-1, 304-2 comprises a plurality of fins 306-1 or 306-2 extending radially outward from central core 62, wherein channels 308-1 are formed between adjacent fins 306-1 and channels 308-2 are formed between adjacent fins 306-2.

First heat exchanger body 304-1 comprises first end 312-1 and second end 314-1, whereby airflow generated by fan 52 flows through channels 308-1 from first end 312-1 to second end 314-1. Second heat exchanger body 304-2 comprises first end 312-2 and second end 314-2, whereby airflow generated by fan 52 flows through channels 308-2 from first end 312-2 to second end 314-2.

### Gap Allows for Additional Airflow Into Second Heat Exchanger Body

The overall height of heat exchanger 302 may be equal to the overall height of heat exchanger 54 depicted in FIG. 2. However, as depicted in FIG. 5, first heat exchanger body 304-1 and second heat exchanger body 304-2 may be coupled to central core 62 but be separated by gap 310 between the second end 314-1 of first heat exchanger body 304-1 and the first end 312-2 of second heat exchanger 304-2. The size of separation in gap 310 between first heat exchanger body 304-1 and second heat exchanger body 304-2 may determine how much second airflow (AF2) is allowed to enter second heat exchanger body 304-2.

In operation of cooling fan 300, fan 52 draws a first airflow (AF1) through first heat exchanger body 304-1 and draw a second airflow (AF2) through gap 310 into second heat exchanger 304-2, whereby a portion of first airflow AF1 and second airflow AF2 mix before the combined airflow (AF3) enters second heat exchanger body 304-2. Thus, first airflow AF1 at a first temperature (e.g., ambient air temperature) enters first heat exchanger body 304-1 and first airflow AF1 exiting first heat exchanger body 304-1 will be at a second temperature that may be approximately equal to the temperature of airflow near the midpoint 60 of heat exchanger 54 depicted in FIG. 2. However, the combined airflow AF3 entering second heat exchanger body 304-2 will be less than the second temperature, allowing heat exchanger 302 to transfer more heat to combined airflow AF3 for better cooling.

### Rotational Offset Causes Turbulent Airflow

Still referring to FIG. 5, second heat exchanger body 304-2 may be rotationally offset an angle 305 relative to first heat exchanger body 304-1 such that first airflow AF1 exiting channels 508-1 of first heat exchanger body 304-1 encounters fins 306-2 of second heat exchanger body 304-2. In this configuration, first airflow AF1 is forced into turbulent flow, resulting in one or more flow characteristics through second heat exchanger body 304-2. For example, a first portion of first airflow AF1 may enter second heat exchanger body 304-2 and mix with second airflow AF2, wherein the combined airflow (AF3) has a lower temperature than the temperature of first airflow AF1 exiting first heat exchanger body 304-1. As another example, the combined airflow AF3 may be more turbulent, whereby the fluid field does not develop and the heat transfer capacity of the combined airflow AF3 is increased. The angle 305 of rotational offset between first heat exchanger body 304-1 and second heat exchanger body 304-2 may be any number of degrees (or portions thereof) that align a fin 306 of the second plurality of fins 306-2 relative to a channel 308 of the first plurality of channels 308-1. In some embodiments, the angle 305 of rotational offset may depend on one or more of the number of fins 306 in the second plurality of fins 306-2, the width of each channel 308 in the first plurality of channels 308-1. In some embodiments, the angle 305 of rotational offset may be less than five degrees. The angle 305 of rotational offset may be measured between fins 306 on each heat exchanger body 304-1 and 304-2. In some embodiments, heat exchanger bodies 304-1 and 304-2 comprise connectors 316-1 and 316-2, respectively, and the angle 305 of rotational offset between heat exchanger bodies 304-1 and 304-2 may be measured between connectors 316-1 and 316-2.

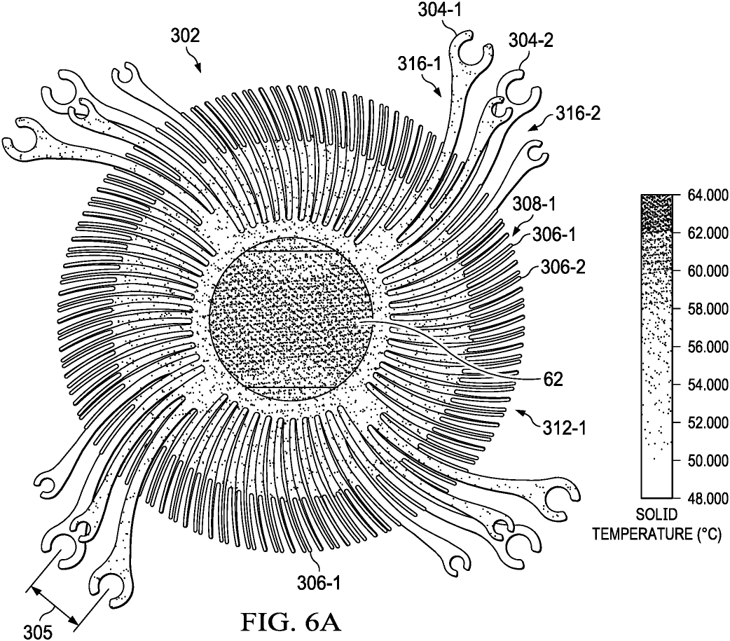

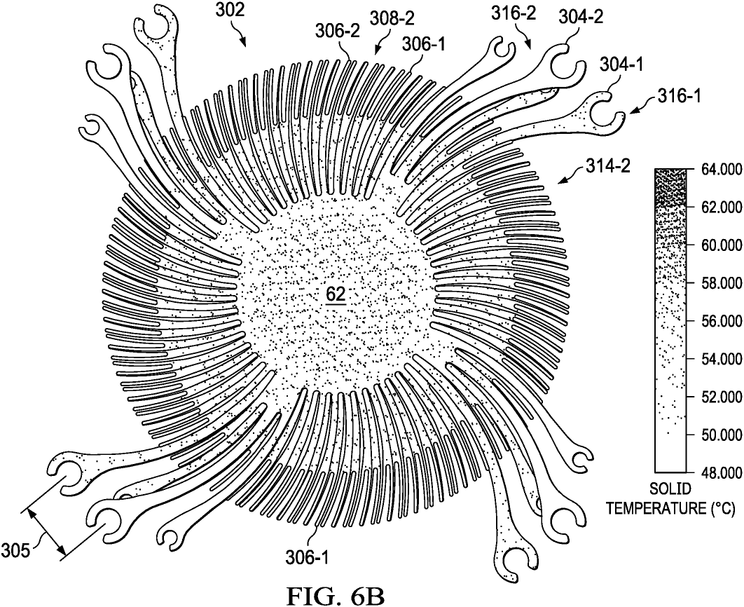

FIGS. 6A and 6B depict simulated temperature profiles of one embodiment of heat exchanger 302 for use in a cooling system for an information handling system 100. As depicted in FIG. 6A, first end 312-1 of first heat exchanger body 304-1 has a first temperature. As depicted in FIG. 6B, second end 314-2 of second heat exchanger 304-2 has a temperature that is higher than the first temperature.

The first temperature may be approximately equal to the temperature of first end 64 of heat exchanger 54.

Comparing the simulated temperature profiles of FIGS. 6A-6B with the simulated temperature profiles of FIGS. 4A-4B, embodiments with a split-level sunflower-type heat exchanger (such as depicted in FIG. 5) provide improved cooling over a single sunflower-type heat exchanger (such as depicted in FIG. 2). In each case, central core 62 may be subjected to heat corresponding to 65 W of power. Also, the distance between first end 64 and second end 66 of heat exchanger 54 depicted in FIG. 2 is equal to the distance between first end 312-1 of first heat exchanger body 304-1 and second end 314-2 of second heat exchanger body 304-2 of heat exchanger 302. Thus, even though the total surface area of fins 306 in heat exchanger 302 may be less than the total surface area of fins 58 in heat exchanger 54 due to gap 310, heat exchanger 302 may utilize a better cooling strategy for cooling information handling system 100.

The above disclosed subject matter is to be considered illustrative, and not restrictive, and the appended claims are intended to cover all such modifications, enhancements, and other embodiments which fall within the true spirit and scope of the disclosure. Thus, to the maximum extent allowed by law, the scope of the disclosure is to be determined by the broadest permissible interpretation of the following claims and their equivalents, and shall not be restricted or limited by the foregoing detailed description.

1. A heat exchanger for an information handling system, the heat exchanger comprising:
a central core;
a first heat exchanger body comprising a first plurality of fins extending radially outward from the central core; and
a second heat exchanger body comprising a second plurality of fins extending radially outward from the central core; wherein:
the first heat exchanger body is separated from the second heat exchanger body by a gap; and
the first heat exchanger body is rotationally offset at an angle relative to the second heat exchanger body.

2. The heat exchanger of claim 1, wherein the angle of rotational offset between the first heat exchanger body and the second heat exchanger body is sized to cause turbulence in airflow entering the second heat exchanger body.

3. The heat exchanger of claim 2, wherein the angle of rotational offset between the first heat exchanger body and the second heat exchanger body is sized to align each fin of the first plurality of fins with a respective channel disposed between each of two adjacent fins of the second plurality of fins.

4. The heat exchanger of claim 2, wherein the first heat exchanger body is rotationally offset at an angle less than five degrees relative to the second heat exchanger body, wherein the angle is measured between a first connector on the first heat exchanger body and a second connector on the second heat exchanger body.

5. The heat exchanger of claim 1, wherein the gap between the first heat exchanger body and the second heat exchanger body is sized to cause turbulence in airflow entering the second heat exchanger body.

6. A cooling system for an information handling system, the cooling system comprising:
a fan operable to draw air in an axial direction;
a heat exchanger positioned coaxial with the fan, the heat exchanger comprising:
a central core;
a first heat exchanger body comprising a first plurality of fins extending radially outward from the central core; and
a second heat exchanger body comprising a second plurality of fins extending radially outward from the central core; wherein:
the first heat exchanger body is separated from the second heat exchanger body by a gap; and
the first heat exchanger body is rotationally offset an angle relative to the second heat exchanger body.

7. The cooling system of claim 6, wherein the angle of rotational offset between the first heat exchanger body and the second heat exchanger body is sized to cause turbulence in airflow entering the second heat exchanger body.

8. The cooling system of claim 7, wherein the angle of rotational offset between the first heat exchanger body and the second heat exchanger body is sized to align a fin of the first plurality of fins with a respective channel disposed between each of two adjacent fins of the second plurality of fins.

9. The cooling system of claim 7, wherein the first heat exchanger body is rotationally offset at an angle less than five degrees relative to the second heat exchanger body.

10. The cooling system of claim 6, wherein the gap between the first heat exchanger body and the second heat exchanger body is sized to cause turbulence in airflow entering the second heat exchanger body.

11. A method of manufacturing a cooling system for an information handling system, the method comprising:
assembling a heat exchanger comprising:
positioning a first heat exchanger body on a central core, the first heat exchanger body comprising a first plurality of fins extending radially outward from the central core;
positioning a second heat exchanger body on the central core rotationally offset an angle relative to the first heat exchanger body, the second heat exchanger body comprising a second plurality of fins extending radially outward from the central core, wherein the second heat exchanger body is positioned with a gap between the first heat exchanger body and the second heat exchanger body; and
positioning the heat exchanger coaxially with a fan.

12. The method of claim 11, wherein positioning the second heat exchanger on the central core rotationally offset relative to the first heat exchanger body comprises positioning the second heat exchanger on the central core rotationally offset an angle sized to cause turbulence in airflow entering the second heat exchanger body.

13. The method of claim 12, wherein positioning the second heat exchanger on the central core rotationally offset relative to the first heat exchanger body comprises positioning the second heat exchanger on the central core rotationally offset an angle sized to align a fin of the first plurality of fins relative to a channel between two adjacent fins of the second plurality of fins.

14. The method of claim 11, wherein positioning the second heat exchanger on the central core rotationally offset relative to the first heat exchanger body comprises positioning the second heat exchanger on the central core rotationally offset an angle less than five degrees relative to the first heat exchanger body.

15. The method of claim 11, wherein positioning the second heat exchanger on the central core comprises forming the gap between the first heat exchanger body and the second heat exchanger body with a size to cause turbulence in airflow entering the second heat exchanger body.
